(19) United States
(12) Patent Application Publication
(10) Pub. No.: US 2019/0189694 A1
(43) Pub. Date: Jun. 20, 2019

(54) Image Sensor and Forming Method Thereof

(71) Applicant: Huaian Imaging Device Manufacturer Corporation, Huaian (CN)

(72) Inventors: Yuping MU, Huaian (CN); Shijie CHEN, Huaian (CN); Xiaolu HUANG, Huaian (CN)

(21) Appl. No.: 16/121,279

(22) Filed: Sep. 4, 2018

(30) Foreign Application Priority Data
Dec. 15, 2017 (CN) 201711351450.5

(51) Int. Cl. H01L 27/28; H01L 27/30

(52) U.S. Cl. CPC H01L 27/286; H01L 27/14621; H01L 27/307

(57) ABSTRACT

An image sensor and a forming method thereof are disclosed. The image sensor includes: a semiconductor substrate, the semiconductor substrate has photodiodes therein; and a dielectric layer, the dielectric layer is located on a surface of the semiconductor substrate; and photoelectric conversion films formed in the dielectric layer, wherein the photoelectric conversion films are in one-to-one correspondence aligned with the photodiodes, so that light passing through the photodiodes is transmitted to the corresponding photoelectric conversion films. The solution provided in the present disclosure can effectively improve the quantum efficiency of the image sensor. The photoelectric conversion films are made of organic photoelectric materials. The photoelectric conversion films have photosensitive area, which is equal or larger than the photosensitive area of the corresponding photodiode.

### CROSS REFERENCES TO RELATED APPLICATIONS

This application claims the benefit of priority to Chinese Patent Application No. CN201711351450.5, entitled “Image Sensor and Forming Method Thereof”, filed with SIPO on Dec. 15, 2017, the contents of which are incorporated herein by reference in its entirety.

### TECHNICAL FIELD

The present disclosure relates to the technical field of semiconductor devices, and in particular, to an image sensor and a forming method thereof.

### BACKGROUND

An image sensor is a semiconductor device for converting optical image signals into electrical signals. Among a variety of image sensors, complementary metal oxide semiconductor (CMOS for short) image sensors have been widely applied because of their advantages of small size, low power consumption and low cost.

The existing CMOS image sensors for mobile phones mainly include two type devices: front-side illumination (FSI for short) CMOS image sensors and back-side illumination or back illumination (BSI for short) CMOS image sensors, which have different requirements. The back-side illumination CMOS image sensors on mobile phones are characterized with more demanding photoelectric conversion effect (i.e., high quantum conversion efficiency).

However, in practical applications, after light arrives at a photosensitive diode (also referred to as a photodiode) of a CMOS image sensor, certain wavelength light, e.g., red light with longer wavelength, cannot be fully absorbed by the existing CMOS sensor because of the narrow silicon band gap window from the photosensitive diode. Light with longer wavelength like red will penetrate the sensor and miss the photo-electric conversion process in the photosensitive diode, resulting in loss of quantum efficiency of the device. There is a need to improve the quantum efficiency of an existing image sensor.

### SUMMARY

The present disclosure provides an image sensor, comprising: a semiconductor substrate, the semiconductor substrate has photodiodes; and a dielectric layer, the dielectric layer is located on a surface of the semiconductor substrate; and photoelectric conversion films formed in the dielectric layer, wherein the positions of the photoelectric conversion films are in one-to-one correspondence with the positions of the photodiodes, so that light passing through the photodiodes is transmitted to the corresponding photoelectric conversion films.

Optionally, the photoelectric conversion films are organic photoelectric conversion films.

Optionally, MOS transistors are further formed in the semiconductor substrate, and the dielectric layer covers gates of the MOS transistors.

Optionally, a photosensitive area of each photoelectric conversion film is not smaller than a photosensitive area of the corresponding photodiode.

Optionally, an output end of each photodiode is electrically connected with the corresponding photoelectric conversion film.

Optionally, an edge of each photoelectric conversion film is bent toward the corresponding photodiode.

The present disclosure further provides a forming method of an image sensor, comprising: providing a semiconductor substrate, the semiconductor substrate having photodiodes therein; and forming a dielectric layer on a surface of the semiconductor substrate, the dielectric layer having photoelectric conversion films therein, wherein the positions of the photoelectric conversion films are in one-to-one correspondence with the positions of the photodiodes, so that light passing through the photodiodes is transmitted to the corresponding photoelectric conversion films.

Optionally, the photoelectric conversion films are organic photoelectric conversion films.

Optionally, forming a dielectric layer on a surface of the semiconductor substrate comprises: forming a first dielectric layer on the surface of the semiconductor substrate; etching the first dielectric layer to form grooves, the positions of the grooves being in one-to-one correspondence with the positions of the photodiodes; filling the grooves with the photoelectric conversion films; and forming a second dielectric layer, the second dielectric layer covering the photoelectric conversion films and the first dielectric layer, wherein the dielectric layer comprises the first dielectric layer and the second dielectric layer.

Optionally, an edge of each photoelectric conversion film is bent toward the corresponding photodiode.

### BRIEF DESCRIPTION OF THE DRAWINGS

FIG. 1 shows a cross sectional view of an image sensor structure according to an embodiment of the present disclosure.

FIG. 2 shows a flow chart of a forming method of an image sensor according to an embodiment of the present disclosure.

FIG. 3 to FIG. 8 is a step by step illustration in the forming process of the image sensor according to an embodiment of the present disclosure.

FIG. 9 illustrates the working principle of a single pixel unit in the image sensor according to an embodiment of the present disclosure.

FIG. 10 shows a schematic circuitry diagram of the pixel unit shown in FIG. 9.

FIG. 11 shows the time sequence diagram of the circuitry for the pixel unit shown in FIG. 9.

### DETAILED DESCRIPTION OF THE PREFERRED EMBODIMENTS

The foregoing objectives, features, and advantages of the present disclosure will become more apparent from the following detailed description of specific embodiments of the disclosure in conjunction with the accompanying drawings. In the detailed description of the embodiments of the present disclosure, for convenience of description, the schematic diagram will be partially enlarged not according to an ordinary ratio, and the schematic diagram is only an example, which should not limit the protection scope of the present disclosure. In addition, three-dimensional space dimensions of length, width, and depth should be comprised in actual production.

As described in the background, the existing image sensor cannot completely absorb incident light and has low quantum efficiency.

In order to solve the above technical problem, an embodiment of the present disclosure provides an image sensor, comprising: a semiconductor substrate, the semiconductor substrate has photodiodes therein; and a dielectric layer, the dielectric layer is located on a surface of the semiconductor substrate, and photoelectric conversion films are formed in the dielectric layer, wherein the positions of the photoelectric conversion films are in one-to-one correspondence with the positions of the photodiodes, so that light passing through the photodiodes is transmitted to the corresponding photoelectric conversion films.

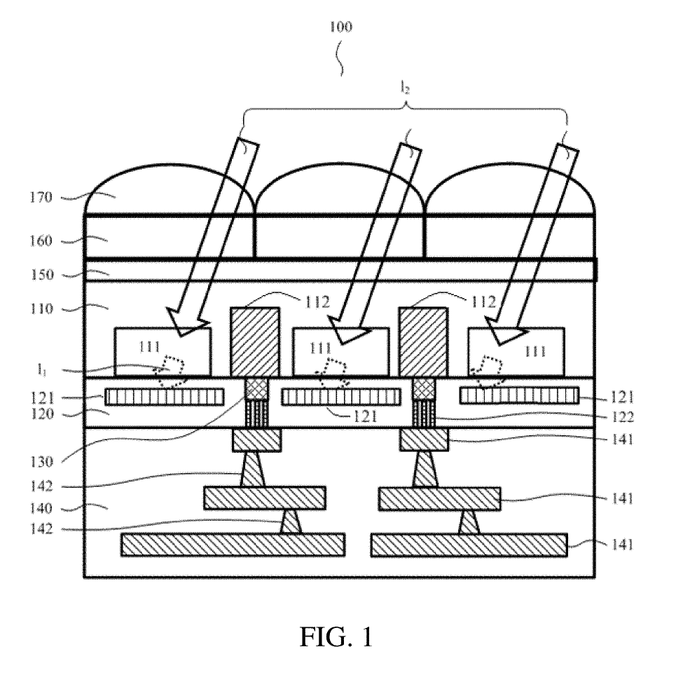

FIG. 1 shows a cross sectional view of an image sensor according to an embodiment of the present disclosure. The image sensor is a BSI CMOS image sensor, or a FSI CMOS image sensor.

Next, the back-side illumination CMOS image sensor will be described in detail as an example.

Specifically, referring to FIG. 1, the image sensor 100 includes a semiconductor substrate 110, wherein the semiconductor substrate 110 may have photodiodes 111; and a dielectric layer 120, wherein the dielectric layer 120 is located on the bottom surface of the semiconductor substrate 110, and photoelectric conversion films 121 is formed in the dielectric layer 120; the photoelectric conversion film 121 is under the photodiode 111, such that light l₁ passing through the photodiode 111 can be transmitted to the corresponding photoelectric conversion film 121.

More specifically, since the image sensor 100 is a back-side illumination CMOS image sensor, the photodiodes 111 may be formed in the back surface of the semiconductor substrate 110, and the dielectric layer 120 may be located on the front surface of the semiconductor substrate 110. At a position shown in FIG. 1, the photoelectric conversion films 121 are located under the corresponding photodiodes 111. This is determined based on a transmission path of incident light l₂, which first arrives at the photodiodes 111 when entering the image sensor 100. Then, part of the light with longer wavelength in red or near infrared, not absorbed by the photodiode because of the narrow silicon band gap window arrives at the photoelectric conversion films 121.

Further, the image sensor 100 may further comprise grids 112. The grids 112 define openings corresponding to the photodiodes 111 within the semiconductor substrate 110.

Further, the image sensor 100 may further comprise color filter 160 and lenses 170. The color filter 160 and the lenses 170 are in correspondence to the openings defined by the grids 112.

Preferably, the lenses 170 may be micro lenses.

Further, the color filter 160 may be red color filter, green color filter or blue color filter.

In a preferred example, the grids 112 are at least flush with the color filter 160 to better avoid light crosstalk.

As a nonrestrictive embodiment, for color filter of different colors, the photosensitive thickness and/or the photosensitive area of the photoelectric conversion films 121 corresponding to the photodiodes 111 at the openings thereof may be different.

For example, for red light with a longer wavelength, the thickness of the photosensitive layer in photoelectric conversion film 121 corresponding to the photodiode 111 arranged in the opening where the red color filter lens is located may be thicker to sufficiently block red light projecting through the photodiode 111.

Preferably, the photoelectric conversion films 121 may be organic photoconductive thin-films (OPF for short). Preferably, an active layer in the organic photoelectric conversion film contains polymer compound, which may contain one polymer compound, or two or more polymer compounds. The polymer compound may be an electron donor compound and/or an electron acceptor compound. In order to improve the charge transport property of the active layer, the electron donor compound and the electron acceptor compound may be used together in the active layer. Preferably, the active layer contains a conjugated polymer compound and a fullerene derivative. For example, an organic thin film containing a conjugated polymer compound and a fullerene derivative maybe used as the active layer.

Further, MOS transistors may be further formed within the semiconductor substrate 110, and the dielectric layer 120 may cover gates 130 of the MOS transistors.

As a nonrestrictive example, the dielectric layer 120 may be an inter layer dielectric (ILD) layer as an isolator between the semiconductor substrate 110 and a first layer of metal.

Further, the photosensitive area of the photoelectric conversion film 121 may be larger than the photosensitive area of the corresponding photodiode 111 to ensure that all the light l₂ penetrating the photodiode 111 can be captured. For example, in a plane where a surface of the semiconductor substrate 110 is located, a planar area of the photoelectric conversion film 121 is not smaller than the photosensitive area of the corresponding photodiode 111 (e.g., located above the photoelectric conversion film 121).

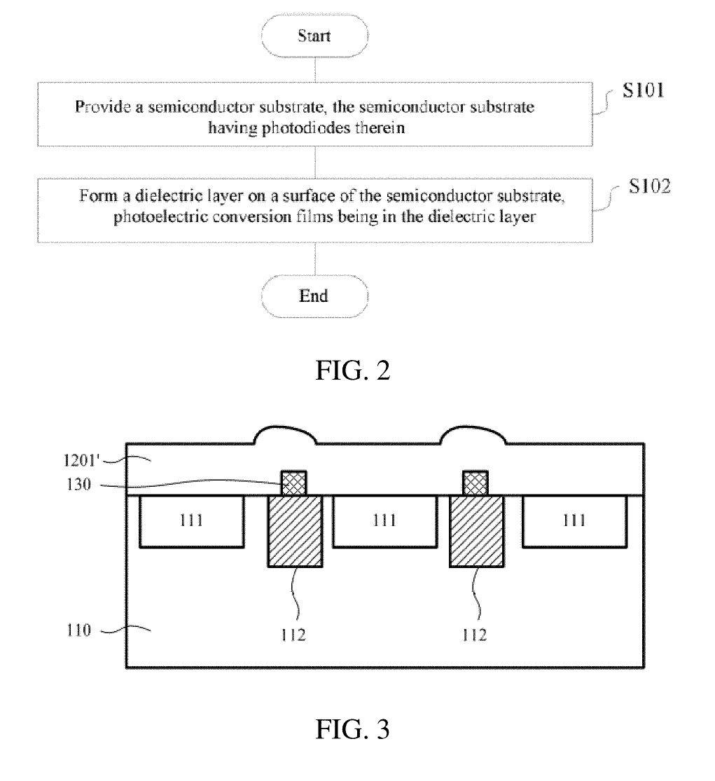

FIG. 2 shows a flow chart of a formation method of an image sensor according to an embodiment of the present disclosure. A formation process is used for forming at least part of a structure in the image sensor 100 shown in FIG. 1 above.

Specifically, in this embodiment, the forming method of the image sensor comprises the following steps:

Step S101, providing a semiconductor substrate, the semiconductor substrate has photodiodes disposed in one surface.

Step S102, forming a dielectric layer on this surface of the semiconductor substrate, photoelectric conversion films are provided in the dielectric layer.

The photoelectric conversion films are in one-to-one correspondence to the photodiodes, so that light passing through the photodiodes is transmitted to the corresponding photoelectric conversion films. Meanwhile, in this embodiment, each photoelectric conversion film is located under its corresponding photodiode.

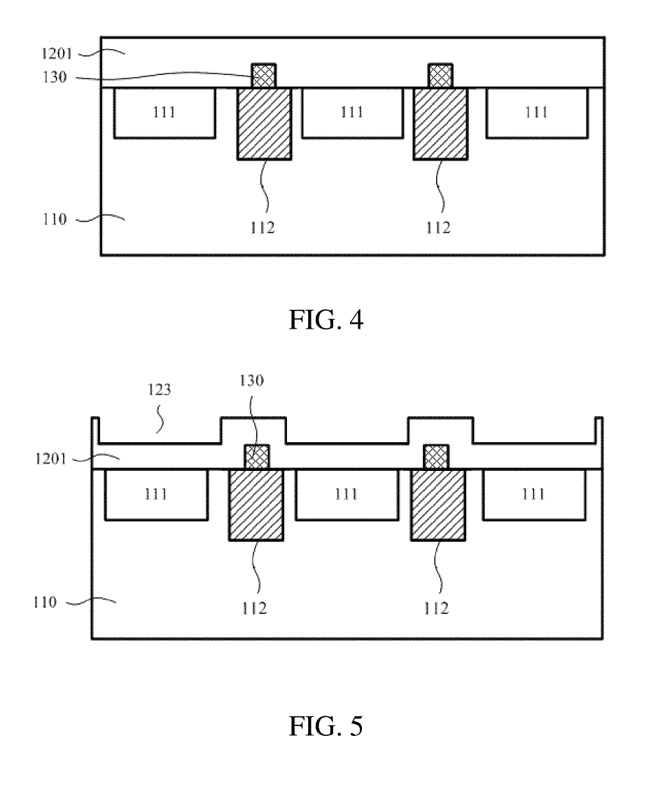

As a nonrestrictive embodiment, the semiconductor substrate may be a silicon substrate suitable for a back-side illumination CMOS image sensor. The forming method of the image sensor 100 shown in FIG. 1 will be described in detail below with reference to FIGS. 3 to 8.

Referring to FIG. 3, a semiconductor substrate 110 is provided first, in which photodiodes 111 and MOS transistors 130 are provided. The adjacent photodiodes 111 are separated by a grid 112 made of a shielding material, so as to prevent light crosstalk and electron crosstalk.

Next, a dielectric material 1201′ is deposited on a surface (e.g., front surface) of the semiconductor substrate 110 to cover gates 130 of the MOS transistors, which exposes the surface of the semiconductor substrate 110.

Preferably, the dielectric material 1201′ is a silicon oxide or silica material.

Preferably, the shielding material 112 is an insulating material such as an oxide. or

The shielding material can also be some metals that prevent light crosstalk.

Further, referring to FIG. 4, a surface of the dielectric material 1201′ is planarized to form a first dielectric layer 1201 on a surface of the semiconductor substrate 110.

Preferably, the planarization is achieved based on a chemical mechanical polishing process.

Further, referring to FIG. 5, a surface of the first dielectric layer 1201 is spin-coated with a photoresist (e.g., a lithography photoresist) and then exposed to pattern of photoelectric conversion films 121 on the surface of the first dielectric layer 1201. The first in the dielectric layer 1201 to form grooves 123, and all the grooves 123 formed on the surface of the first dielectric layer 1201 prepare for deposition of the photoelectric conversion films 121. In addition, the grooves 123 align to the photodiodes 111.

Preferably, the grooves 123 are formed by dry etching process.

Further, referring to FIG. 6, a photoelectric conversion film material 121′ is formed on a surface of the first dielectric layer 1201 filling the grooves 123. Specifically, the photoelectric conversion film material 121′ may be formed by a coating method with a solution containing the active layer forming material mentioned above and a solvent, and for example, may be formed by a coating method using a solution containing a conjugated polymer compound, a fullerene derivative and a solvent. The solvent may be a hydrocarbon series solvent such as toluene or xylene, a halogenated saturated hydrocarbon series solvent such as carbon tetrachloride, chloroform or methylene chloride, a halogenated unsaturated hydrocarbon series solvent such as chlorobenzene, dichlorobenzene or trichlorobenzene, or an ether solvent such as tetrahydrofuran or tetrahydropyrane. The coating method for the solution of the active layer forming material may be, for example, a spin-coating method.

Further, referring to FIG. 7, a surface of the photoelectric conversion film material 121′ is planarized until the first dielectric layer 1201 is exposed. The photoelectric conversion films 121 are patterned to align with grooves 123.

A planarization method of the photoelectric conversion film material 121′ includes various suitable methods such as CMP.

Further, referring to FIG. 8, a dielectric material is deposited on the exposed surfaces of the first dielectric layer 1201 and the photoelectric conversion films 121; the dielectric material 1201′ then is planarized to form a second dielectric layer on the exposed surfaces of the first dielectric layer 1201 and the photoelectric conversion films 121. The second dielectric layer covers the photoelectric conversion films 121 and the first dielectric layer 1201, wherein the first dielectric layer 1201 and the second dielectric layer jointly form the dielectric layer 120.

Preferably, the first dielectric layer 1201 and the second dielectric layer deposited in this step may be made of the same dielectric material 1201′.

Further, after a device structure shown in FIG. 8 is obtained, flip the device over, now referring back to FIG. 1, a metal interconnection structure 140 may be formed on the surface of the dielectric layer 120 at the same side of the substrate. The color filter 160 and the lenses 170 are placed on the other surface (i.e., a surface opposite to the dielectric layer 120) of the semiconductor substrate 110.

As a nonrestrictive embodiment, in FIG. 1, a third dielectric layer 150 may be formed between the color filter 160 and the semiconductor substrate 110 to seal and protect the semiconductor substrate 110. Preferably, the third dielectric layer 150 may be made of a high dielectric constant (High-K) material.

Further, referring to FIG. 1, the metal interconnection structure 140 may comprise three metal layers 141, and via holes 142.

Further, the metal interconnection structure 140 may be electrically connected with the gates 130 of the MOS transistors through connecting wires 122. Preferably, the connecting wires 122 are copper wires.

Alternatively, the metal interconnection structure 140 may be prepared on another substrate in advance, and is integrally bonded to a surface of the dielectric layer 120 after the device structure shown in FIG. 8 is formed.

As a nonrestrictive embodiment, edges of each photoelectric conversion film 121 may be bent to wrap the corresponding photodiode 111, so that light l₁ passing through each photodiode 111 is not reflected or refracted to next photodiodes 111 and absorbed by the their photoelectric conversion films 121, so as to better avoid crosstalk between adjacent pixels (i.e., the photodiodes 111).

For example, when the grooves 123 shown in FIG. 5 are formed, stepwise etching may be adopted, and etching depth at the edges of each groove 123 may be deeper than etching depth at other regions of the grooves, so that the edge of the groove 123 is bent toward the corresponding photodiode 111.

Or, the etching depth may keep uniform, but each groove 123 is patterned to bend at edges through lithography.

Further, an output end of each photodiode 111 may be electrically connected with the corresponding photoelectric conversion film 121, so that photo-generated charges collected by the photodiode 111 and the corresponding photoelectric conversion film 121 are gathered together to be transmitted within an exposure period to avoid an image trailing phenomenon.

Alternatively, a surface (e.g., a surface irradiated by the light l₁) of the photoelectric conversion film 121 may also be made wavy, which can also avoid light crosstalk between adjacent pixels.

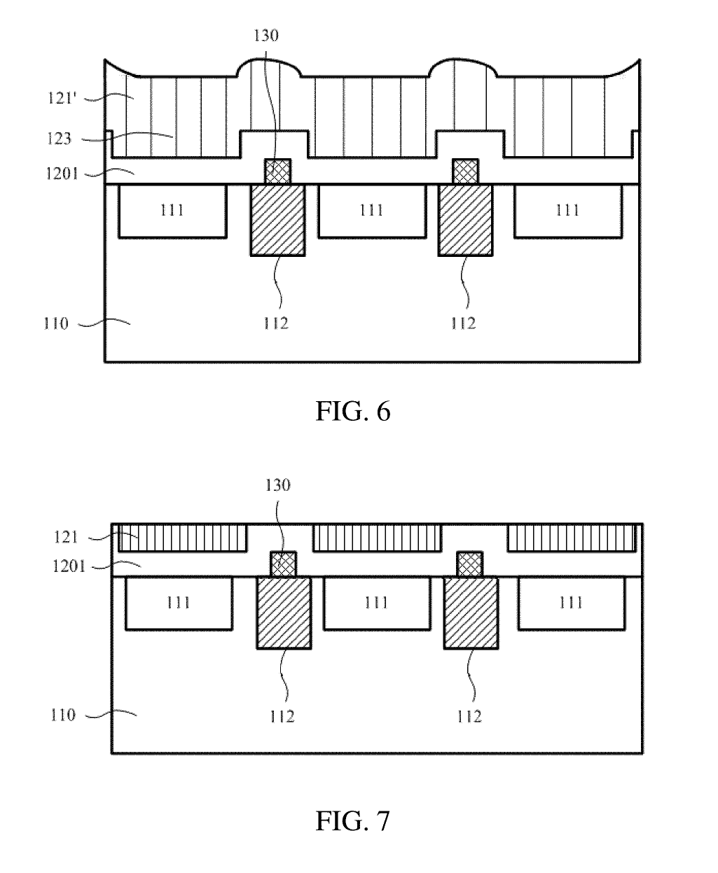

FIG. 9 shows a prospective view of a single pixel unit of the image sensor in a working mode according to an embodiment of the present disclosure. The pixel unit may comprise the photodiode 111 and the corresponding photoelectric conversion film 121 in the image sensor 100 shown in FIG. 1 above.

Specifically, the photodiode 111 may be located in a depletion region of the image sensor, and the corresponding photoelectric conversion film 121 is located on a surface of the photodiode 111. On a transmission path of incident light l₂, light is absorbed mostly by the photodiode 111 and only the longer wavelength light like red or infrared passes through to reach the photoelectric conversion film 121.

More specifically, the semiconductor substrate 110 may be a lightly doped P-type substrate, a P-type well may be formed on the semiconductor substrate 110, and a grid of shallow trench isolation (STI) regions is formed in the P-type wells. The distance between the photodiode 111 and the neighboring STI region is measured through a recessed distance.

Further, an output end of one photodiode 111 and the corresponding photoelectric conversion film 121 may be connected to agate 130 of an MOS transistor in the image sensor. Preferably, the gate 130 is located on a floating (FD) node of the pixel unit.

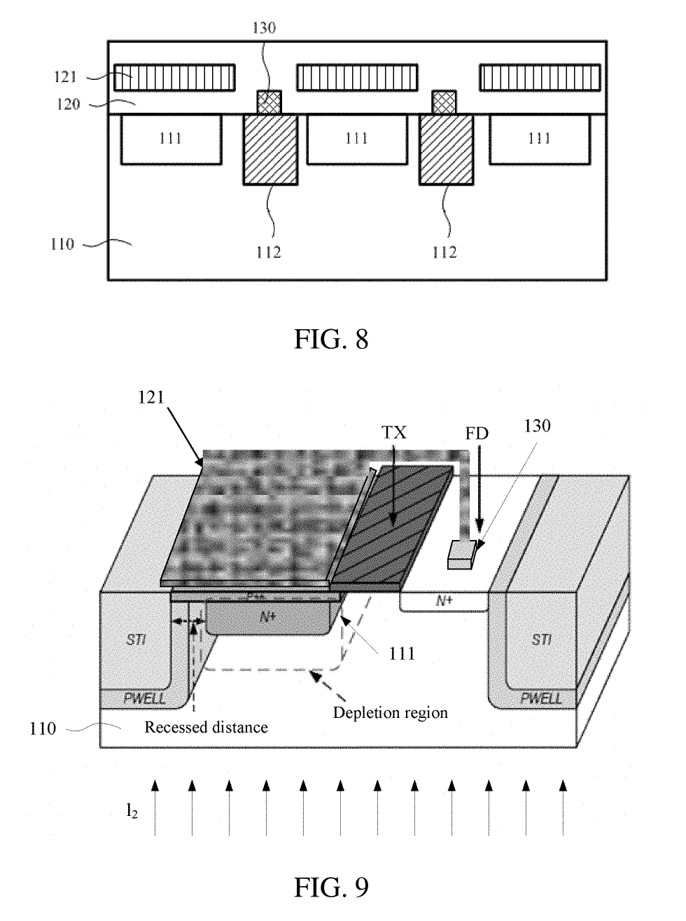

Referring to FIG. 9 and FIG. 10, taking a 4T (transistor) type image sensor as an example, each pixel unit, consisting of a photodiode 111 and a corresponding photoelectric conversion film 121, in the image sensor 100 shown in FIG. 1 may be electrically connected with agate 130 of a corresponding MOS transistor (being a transmission wire TG in this embodiment, also referred to as a transmission wire TX) formed in the semiconductor substrate 110. Thus, the potential on the floating node can directly determine the potential on the gate of a source follower wire SF, and further determine the final output current.

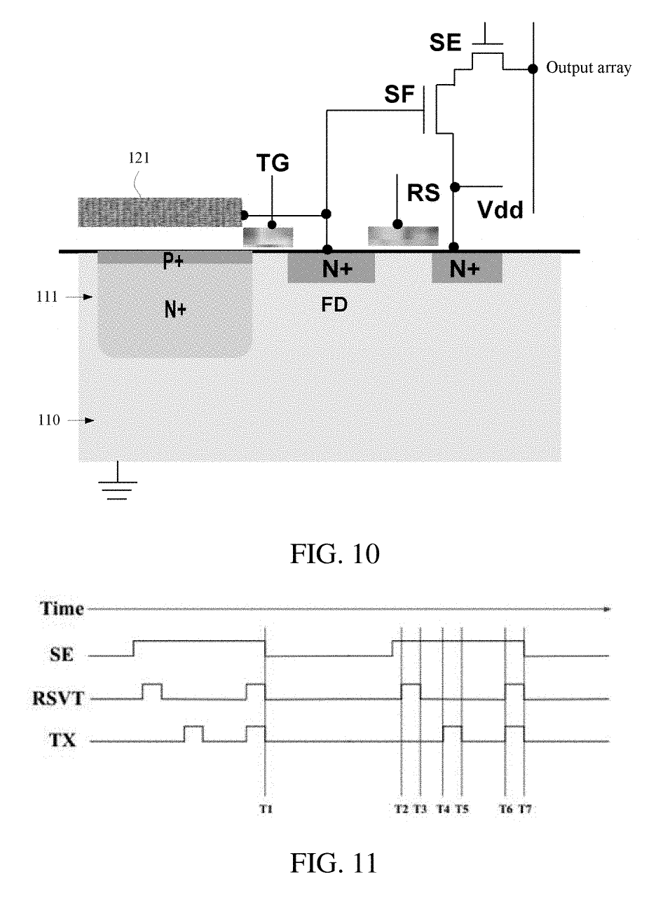

Further, in this embodiment, through a time sequence shown in FIG. 11 generated by the circuitry of FIG. 10, within one image period, by the photons are collected by photodiode 111 and photo-generated electrons are converted by the corresponding photoelectric conversion film 121, finally collected by the floating node via the transmission wire TG.

Further, in the embodiment, in addition to the transmission wire TG and the source follower wire SF, the 4T type image sensor further comprises a reset RS (also referred to as RSVT) and a gating wire SE, wherein a source of the gating wire SE is connected to an output.

Further, in this embodiment, when time sequence shown in FIG. 11 is between T1 and T4, the pixel unit is in an exposure (light collection) phase, and the transmission wire TG is in an off state.

Further, during the period of T2 to T7, the gating wire SE is turned on, and the pixel unit performs a readout operation.

Further, during the period of T2 to T3, the gating wire SE and the reset wire RS are both in on state to reset the floating node.

Further, during the period of T4 to T5, when gating wire SE is on, the transmission wire TG is also turned on to read out light integral signals accumulated by the pixel unit during the time period of T1 to T4 (i.e., collect the converted photo-generated charges).

Further, during the period of T6 to T7, after the light integral signals are transferred, the gating wire SE, the reset wire RS and the transmission wire TG are turned on at the same time to reset the photodiode 111 and the photoelectric conversion film 121 and transfer all the photo-generated charges remaining in the pixel unit to the source of the gating wire SE, so as to prevent this frame of signals from producing an image trailing influence on output of a next frame.

From the above, the image sensor obtained by adopting the solution of this embodiment can achieve photoelectric conversion through the photodiodes, and also can capture the incident light (i.e., the light leaked by the photodiodes) penetrating the photodiodes through the photoelectric conversion films and convert the incident light into photo-generated charges, so as to ensure that the incident light can be completely absorbed and effectively improve the quantum efficiency of the image sensor.

Further, the photoelectric conversion films and the photodiodes are in one-to-one correspondence, which can effectively avoid light crosstalk between adjacent pixels.

Further, an output end of each photodiode is electrically connected with the corresponding photoelectric conversion film, so that the photo-generated charges collected by each photodiode and the corresponding photoelectric conversion film are gathered together to be transmitted within an exposure period to avoid an image trailing phenomenon.

Further, an edge of each photoelectric conversion film is bent toward the corresponding photodiode so as to better avoid light crosstalk between adjacent pixels.

The forming method provided by the present disclosure forms the photoelectric conversion films in the dielectric layer formed on the surface of the semiconductor substrate in the process of forming the image sensor, so as to capture the light leaked by the corresponding photodiodes, thereby improving the quantum efficiency of the finally formed image sensor.

Although the present disclosure is disclosed as above, the present disclosure is not limited thereto. Any person skilled in the art can make various changes and modifications without departing from the spirit and scope of the present disclosure. Therefore, the scope defined by the claims shall prevail the protection scope of the present disclosure.

What is claimed is:

1. An image sensor, comprising:
a semiconductor substrate, comprising a plurality of photodiodes for receiving light; and
a dielectric layer disposed on a first surface of the semiconductor substrate; and
a plurality of photoelectric conversion films patterned in the dielectric layer;
wherein the plurality of photoelectric conversion films each is in one-to-one correspondence aligned to one of the plurality of photodiodes, wherein light passing through the photodiodes is transmitted to the corresponding photoelectric conversion films.

2. The image sensor according to claim 1, wherein the plurality of photoelectric conversion films is made of organic photoelectric materials.

3. The image sensor according to claim 1, further comprising MOS transistors formed under the dielectric layer on the first surface of the semiconductor substrate.

4. The image sensor according to claim 1, wherein the plurality of photoelectric conversion films each comprises a photosensitive area, wherein the photosensitive area is equal or larger than a photosensitive area of the corresponding photodiode.

5. The image sensor according to claim 1, wherein an output end of each of the plurality of photodiodes is electrically connected with the corresponding photoelectric conversion film.

6. The image sensor according to claim 1, wherein an edge of the photoelectric conversion film is bent toward the corresponding photodiode.

7. A method of forming an image sensor, comprising:
providing a semiconductor substrate, having a plurality of photodiodes on the first surface of the semiconductor substrate;
forming a dielectric layer on the first surface of the semiconductor substrate; and
forming a plurality of photoelectric conversion films in the dielectric layer;
wherein the plurality of photoelectric conversion films each is in one-to-one correspondence aligned to one of the plurality of photodiodes, so that light passing through each of the plurality of photodiodes is transmitted to the corresponding photoelectric conversion film.

8. The forming method according to claim 7, wherein the plurality of photoelectric conversion films is made of organic photoelectric conversion materials.

9. The method according to claim 7, wherein the dielectric layer comprises a first dielectric layer and a second dielectric layer;
wherein the method further comprise:
forming the first dielectric layer on the first surface of the semiconductor substrate;
etching the first dielectric layer to form a plurality of grooves, each aligned to one of the plurality of photodiodes in one-to-one correspondence;
filling the plurality of grooves with the plurality of photoelectric conversion films; and
forming the second dielectric layer on the plurality of photoelectric conversion films and the first dielectric layer.

10. The method according to claim 7, wherein the plurality of photoelectric conversion films each has at least an edge bent toward the corresponding photodiode.
